(19) United States
(12) Patent Application Publication
(10) Pub. No.: US 2009/0087992 A1
(43) Pub. Date: Apr. 2, 2009

(54) METHOD OF MINIMIZING VIA SIDEWALL DAMAGES DURING DUAL DAMASCENE TRENCH REACTIVE ION ETCHING IN A VIA FIRST SCHEME

(75) Inventors: Ravi Prakash SRIVASTAVA, Beacon, NY (US); Hermann WENDT, Poughkeepsie, NY (US); Kaushik A. KUMAR, Beacon, NY (US); Nicholson M. LEE, Katonah, NY (US)

Correspondence Address: KATTEN MUCHIN ROSENMAN LLP, 575 MADISON AVENUE, NEW YORK, NY, 10022-2585, US

(73) Assignees: Chartered Semiconductor Manufacturing Ltd., Street Two (SG); Infineon Technologies North America Corp., San Jose, CA (US); International Business Machines Corporation, Armonk, NY (US)

(21) Appl. No.: 11/863,746

(22) Filed: Sep. 28, 2007

(51) Int. Cl. H01L 21/311; H01L 21/44

(52) U.S. Cl. 438/701; 438/675; 257/E21.249; 257/E21.476

(57) ABSTRACT

A method of minimizing undercut of a hard mask in an integrated circuit (IC) structure including steps of providing an IC structure having a substrate, a interlayer dielectric layer, and a hard mask, forming a via in said IC structure, and depositing an organic planarizing layer (OPL) over the IC structure such that it fills the vias formed therein. The method also includes steps of forming a masking structure layer over the OPL, forming an opening in the masking structure that has a critical dimension (CD) smaller than an opening design dimension, anisotropic etching the OPL such that sidewall of the via remains covered with the OPL while forming a trench, and removing any remaining OPL on the sidewalls and trench, wherein the undercut of the sidewalls with respect to the hard mask is minimized by the covering of OPL during the anisotropic etching process.

### BACKGROUND

1. Field of the Invention

The present invention relates generally to the field of semiconductors, particularly to manufacturing methods for fabricating semiconductor devices, and more particularly to the Back-End-Of-Line (BEOL) semiconductor manufacturing process using via first dual damascene processes.

2. Description of the Prior Art

The semiconductor manufacturing process, when likened to an assembly line, includes two major components, namely the Front-End-of-Line (FEOL) which includes the multilayer process of the actual forming of semiconductor devices (transistors, etc.) on a semiconductor substrate, and the Back-End-Of-Line (BEOL) which includes the metallization after the semiconductor devices have been formed. Like all electronic devices, semiconductor devices in a microchip such as an integrated circuit (IC) need to be electronically connected through wiring. In an integrated circuit, such wiring is done through multilayer metallization on top of the multilayered semiconductor devices formed on the semiconductor substrate. The complexity of this wiring becomes immediately appreciable once one realizes that there are usually hundreds of millions or more semiconductor devices (transistors in particular) formed on a single IC, and all these semiconductor devices need to be properly connected. This is accomplished by multilayer metallization, with each metallization layer designated as Metal 1, Metal 2, so on, where Metal 1 is the metallization layer closest to the underlying semiconductor devices to provide local connections among neighboring devices, and other metallization layers provide increasingly global connections from Metal 2 to the top metallization layer. Each metallization layer consists of a grid of metal lines sandwiched between dielectric layers for electrical integrity. Modern semiconductor manufacturing process can involve six or more metallization layers.

Although in the early years of semiconductor industry BEOL was generally less important than FEOL, the recent advancements have changed that equation. Microchip interconnect technology has become a critical challenge for future IC advancements due to the increasing difficulties to reduce signal propagation delay or interference caused by the increasingly dense interconnects. The problem is particularly acute considering that while an increase of metallization density means longer signal delays caused by the interconnects, a corresponding increase of transistor density means shorter signal traveling time between local semiconductor devices, making metallization increasingly a bottleneck in enhancing IC performance.

Enhancements in integrated circuit (IC) density and performance as predicted by Moore's Law have fueled the semiconductor industry and resultant Information Revolution for over 40 years. The fabrication of deep submicron Ultra-Large Scale Integrated (ULSI) circuits requires long interconnects having small contacts and small cross-sections. In the past generation of semiconductor manufacturing process technology, aluminum (Al) and Al alloys have been used as conventional chip wiring materials while tungsten (W) has been used as contact plug between metal layers. The newer generation of the semiconductor manufacturing process technology has made it necessary to replace the Al technology with a technology based on a different metal. The introduction of copper (Cu) metallization served as an enabler for aggressive interconnects scaling due to its lower resistivity as compared with traditional Al metallization as well as improved reliability (such as less electromigration) and generally a reduced number of steps for fabrication.

Developing along with the transition from Al to Cu has been the process of dual damascene etching. Unlike single damascene, dual damascene scheme forms vias and trenches for metal interconnect simultaneously. There are a number of different dual damascene schemes known and used. One such scheme is shown in FIGS. 1-5, where the process steps used to create a dual damascene interconnect structure using the via-first process scheme and the problems attendant thereto are shown.

FIG. 1 shows a schematic cross section of a series of layers formed in the manufacture of an IC 10 prior to formation of vias therein. The wafer 10's layers include a substrate 11, metal lines 13, an etch stop layer 20, a low-k dielectric layer 16, an oxide hard mask 14, an anti-reflective coating 15, and a photo-resist 17. Using known etching and stripping processes, a via 12 is formed therein as shown in FIG. 2. Thereafter, the photo-resist 17, the anti-reflective coating 15 is removed. This etching causes initial damage to the via sidewalls 32.

FIG. 3A, shows a portion of an IC 10 having a slightly more complex arrangement of layers than that of FIGS. 1 and 2, where the via 12 has already been etched by the processes described above. This via 12 has been etched through an oxide hard mask 14, an inter-level dielectric layer (IDL) 16 (possibly a low-k or ultra low-k dielectric), and partially into the etchstop layer 20 with the IDL 16. The integration layer 18 is particularly necessary when using low-k or ultra low-k materials for the IDL 16 for better adhesion and reliability. As show in FIG. 3A, the via 12 is filled with an organic planarizing layer (OPL) 22, which fills the via 12 and covers the hard mask 14. Over the OPL layer 22 is formed a oxide-like overlayer (OLO) 24, an anti-reflective coating 26, and a photo-resist 28. Using lithography processes known to those of skill in the art a pattern 30 for a trench is formed in the photo-resist 28.

The result of formation of the vias and trenches on the wafer 10 are both horizontal and vertical via chains as shown in FIGS. 2B and 2C.

In FIG. 3B shows the effect of etching using a CF₄ chemistry. Namely, the anti-reflective coating 26 and the OLO 24 are etched through as well as a portion of the OPL 22. Next, the photo-resist 28 and anti-reflective coating 26 are removed and the OPL 22 is removed to a level below the oxide hard mask 14 using organic chemistry such as O₂, CO₂, H₂ or N₂ based chemistry, as shown in FIG. 3C. At this point a portion of the sidewall 32 of the via 12 is exposed, this is highlighted in the circled portion of FIG. 3C.

In FIG. 3D the oxide hard mask 14 is opened to the size of the eventual trench. This is sometimes called a hard mask burn and can be accomplished by a fluorine based chemistry including for example, C₄F₈/Ar, CF₄/CH₂F₂/Ar, CF₄/CHF₃/Ar, etc. As can be seen in the circled area of FIG. 3D, the sidewall of the via 12 is exposed to an even greater extent during this hard mask burn. This exposure of the sidewall 32 during the hard mask burn and subsequent steps effects the make up of the sidewall 32 and has a detrimental effect on the manufacture of the semiconductor.

In FIG. 3E, a main etch is undertaken where the trench 34 is formed. This is typically done using, for example, a CF₄/Ar based chemistry. Again as a result of this step more of the sidewall 32 is exposed, which damage the sidewall 32.

In FIG. 3F the OPL layer 22 is finally removed in its entirety using an O₂ or H2 based chemistry. This step alone causes great damage to the sidewall 32.

Finally, in FIG. 3G the etchstop layer 20 in the bottom of the via 12 is removed using a CF₄ or CH₂ F₂ based chemistry to complete the trench 34 and via 12. The result of all of these etch steps and exposure of the sidewall 32 of the via 12 to varying chemistries can be very dramatic because the next step after 3G is to send wafer for dilute hydrogen fluoride (DHF) clean step. This is wet clean step which actually removes all the damaged sidewall (oxide like layer). FIG. 7c is a schematic representation of the wafer 10 following final etch stop 20 removal and DHF clean showing the undercut of the hard mask 14. The undercut is produced at least in part by the ultimate removal of the ILD 16 which has been damaged by the etching processes. FIG. 4 is a photograph of the undercut of the hard mask 14 over the sidewall 32 of the via 12, also called undercut. Much of this undercut is the result of removal of carbon depletion layer by DHF clean which is actually caused by the etching processes and is particularly troublesome when in low-k and ultra low-k dielectric applications and results in an increase in dielectric constant in the IDL 16. For example dramatic differences in the shape of the via can be seen by comparison of FIG. 5 and FIG. 6 which show the unprotected via sidewall after OPL layer 22 etch and following final etchstop 20 removal plus DHF clean in FIG. 6.

The undercut itself is a problem because it causes problem for the barrier layer deposition and hence prevents Cu from properly bonding to the via 12 sidewalls 32. This problem is shown in FIG. 7D. This improper bonding results in device reliability issues for devices manufactured using this process. Accordingly, there is a need for a dual damascene process that will overcome the shortcomings of the currently used processes such as those discussed above.

### SUMMARY OF THE INVENTION

One aspect of the present invention is directed to a method of minimizing undercut of a hard mask in an integrated circuit (IC) structure including steps of providing an IC structure having a substrate, a interlayer dielectric layer, and a hard mask, forming a via in said IC structure, and depositing an organic planarizing layer (OPL) over the IC structure such that it fills the vias formed therein. The method also includes steps of forming a masking structure layer over the OPL, forming an opening in the masking structure that has a critical dimension (CD) smaller than an opening design dimension, anisotropic etching the OPL such that sidewall of the via remains covered with the OPL while forming a trench, and removing any remaining OPL on the sidewalls and trench, wherein the undercut of the sidewalls with respect to the hard mask is minimized by the covering of OPL during the anisotropic etching process.

The present invention will now be described in more complete detail, with frequent reference being made to the figures identified below.

### BRIEF DESCRIPTION OF THE FIGURES

FIG. 1 is a schematic view of an IC prior to via etch;

FIG. 2 is a schematic view of an IC following via etch using known techniques;

FIGS. 2B-2C show horizontal and vertical via chains formed in an IC;

FIGS. 3A-3G are a schematic representation of an IC undergoing dual damascene processing using known techniques;

FIG. 4 is a photograph of a trench and via formed using dual damascene techniques, showing a hard mask undercut;

FIG. 5 is a photograph of a via and trench structure after OPL etch with no protection of the via sidewall;

FIG. 6 is a photograph of a via and trench structure with bad undercut;

FIG. 7a is a schematic representation of an IC showing a via structure formed using known techniques following further deposition OPL, OLO, anti-reflective layers, lithography of a photo resist layer and finish the dual damascene photo masking;

FIG. 7b is a schematic representation of the IC of FIG. 7a following etching, showing damaged ILD layer on the sidewalls of the trench and via structures;

FIG. 7c is a schematic representation of a via and trench structure formed using known techniques and having a hard mask undercut caused by removal of the damaged layer by dilute hydrogen fluoride (DHF) clean shown in FIG. 7b;

FIG. 7d is a schematic representation of a via and trench structure showing the problem area for barrier metallization;

FIG. 8 is a schematic view of an IC undergoing a first step in the method of the present invention with the CD decreased approximately 20% from the design dimension;

FIG. 8a is a schematic view of an IC undergoing a first step in a method of the present invention with the CD decreased by a taper formed in the OLO layer.

FIG. 9 is a schematic view of an IC undergoing a second step in the method of the present invention;

FIG. 9a is a schematic view of an IC undergoing a second step in a method of the present invention with the CD decreased by a taper formed in the OLO layer;

FIG. 10 is a schematic view of an IC undergoing a third step in the method of the present invention;

FIG. 11 is a schematic view of an IC undergoing a fourth step in the method of the present invention;

FIG. 12 is a schematic view of an IC undergoing a fifth step in the method of the present invention;

FIG. 13 is a schematic view of an IC after undergoing a sixth and final step with dilute hydrogen fluoride (DHF) clean in the method of the present invention;

FIG. 14 is a schematic view of a trench only portion of an IC undergoing the first step of the method of the present invention with the CD reduced by at least 20% from the design dimension;

FIG. 15 is a schematic view of a trench only portion of an IC undergoing the second step of the method of the present invention where the OPL layer is over etched, removing any footing at the bottom of the OPL and creates an opening for the trenches which actually compensates for the reduction of CD at OLO step;

FIG. 16 is a schematic of a trench only portion of an IC after undergoing etching, ashing, and etch stop removal showing damaged areas in the sidewall of the trench;

FIG. 17 shows the trench only portion of FIG. 17 following dilute HF cleaning to remove the damaged portion of the ILD layer;

FIG. 18 is a schematic view of a trench only portion of an IC undergoing the first step of the method of the present invention with the CD reduced by a tapered OLO layer.

FIG. 19 is a schematic view of a trench only portion of an IC undergoing the second step of the method of the present invention where the OPL layer is over etched to compensate for the reduction in CD caused by a tapered OLO layer.

### DETAILED DESCRIPTION

As described above with reference to a known dual damascene process, via sidewalls are damaged during a via strip step, and then are further damaged by processing steps including the trench etch, etc. To minimize this damage, one aspect of the present invention is directed to a scheme which protects the sidewalls during the trench reactive ion etch (RIE) process, in a via first dual damascene process.

In one aspect of the present invention, an etch sequence is used on masking structure for example an oxide-like over-layer (OLO) and an OPL integration scheme where the via sidewalls closest to the trench are protected by the OPL during OPL etch, an oxide hard mask open and main etches to avoid any unnecessary exposure to the sidewalls. In addition it has been found that this process does not affect the CD of trench only structures, having no via sidewalls to be concerned with.

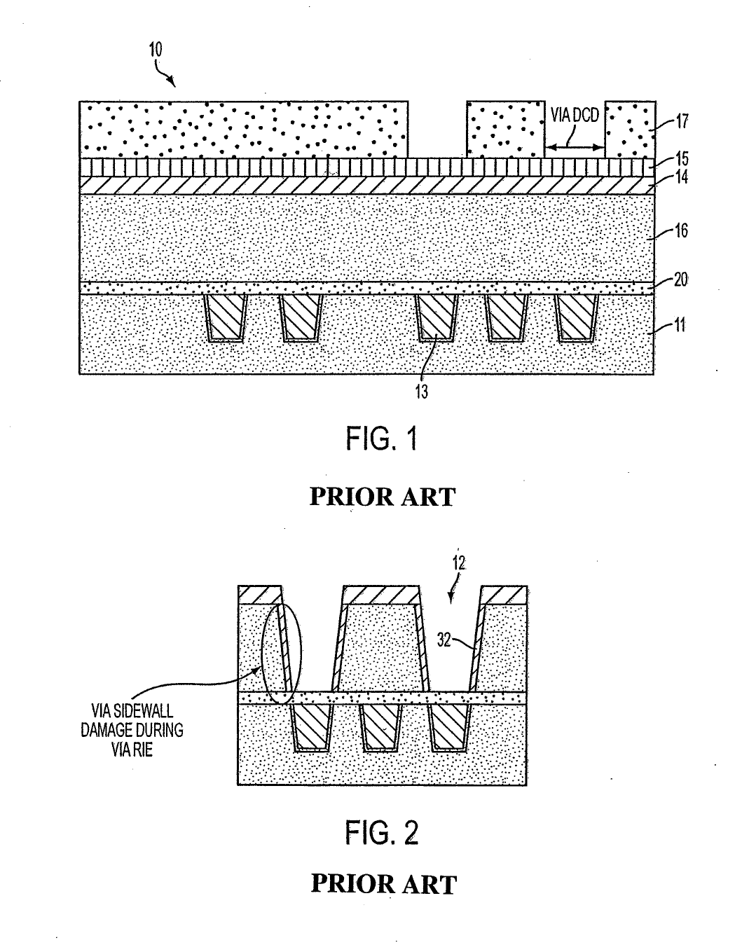

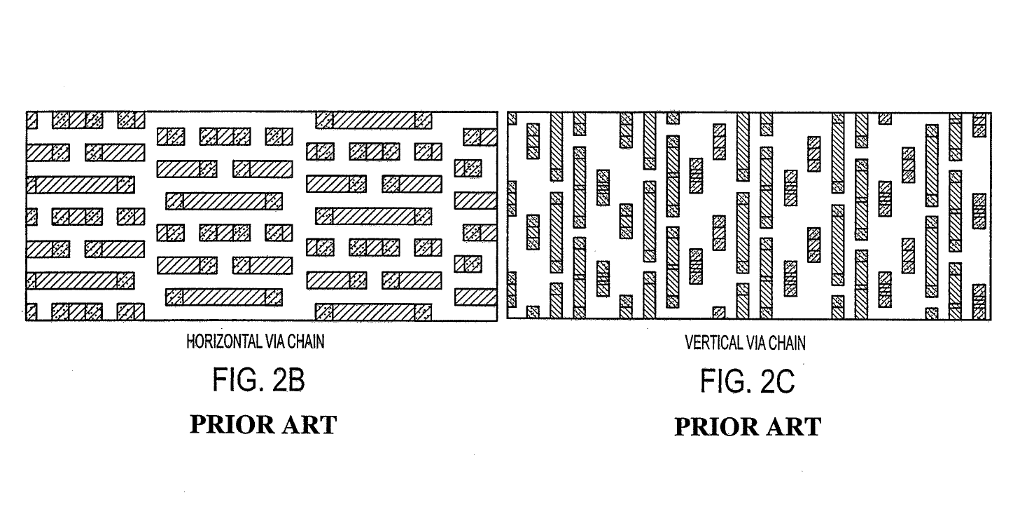

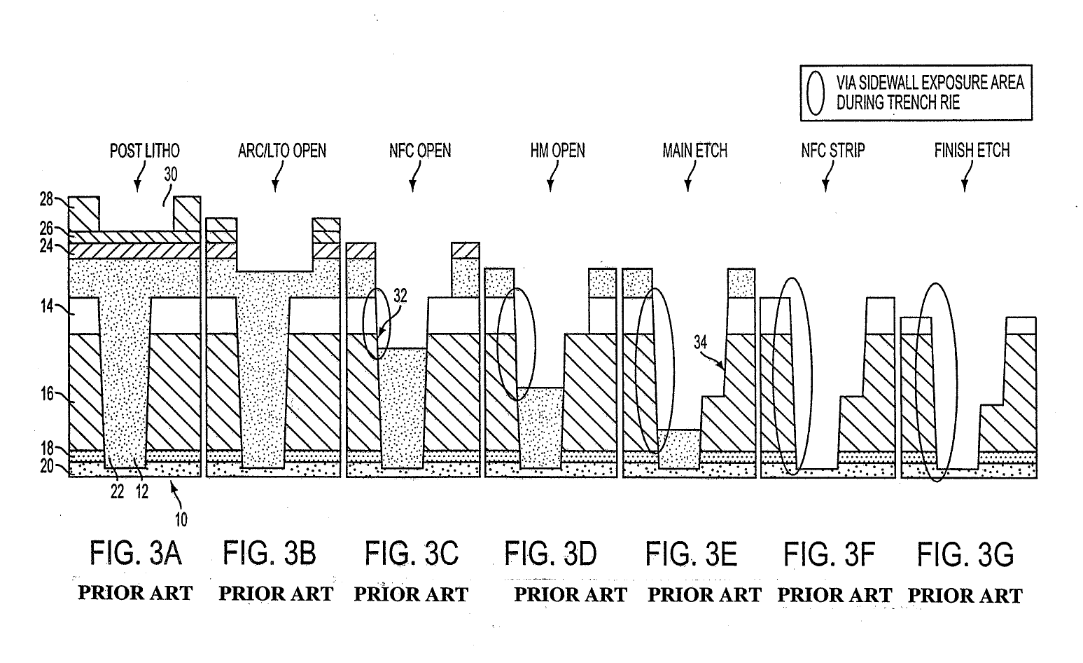

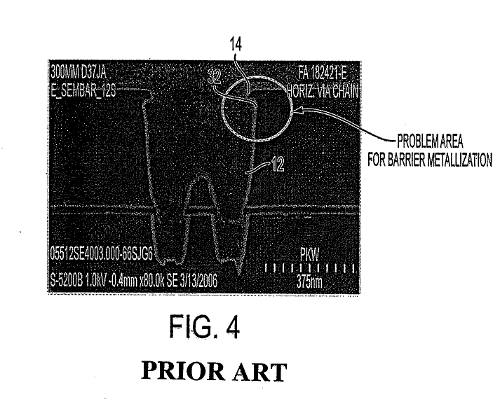

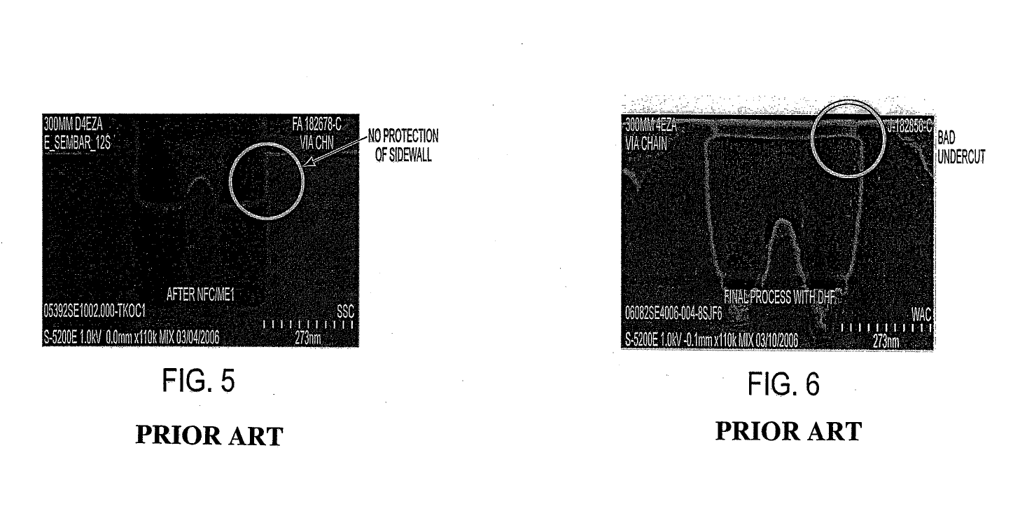

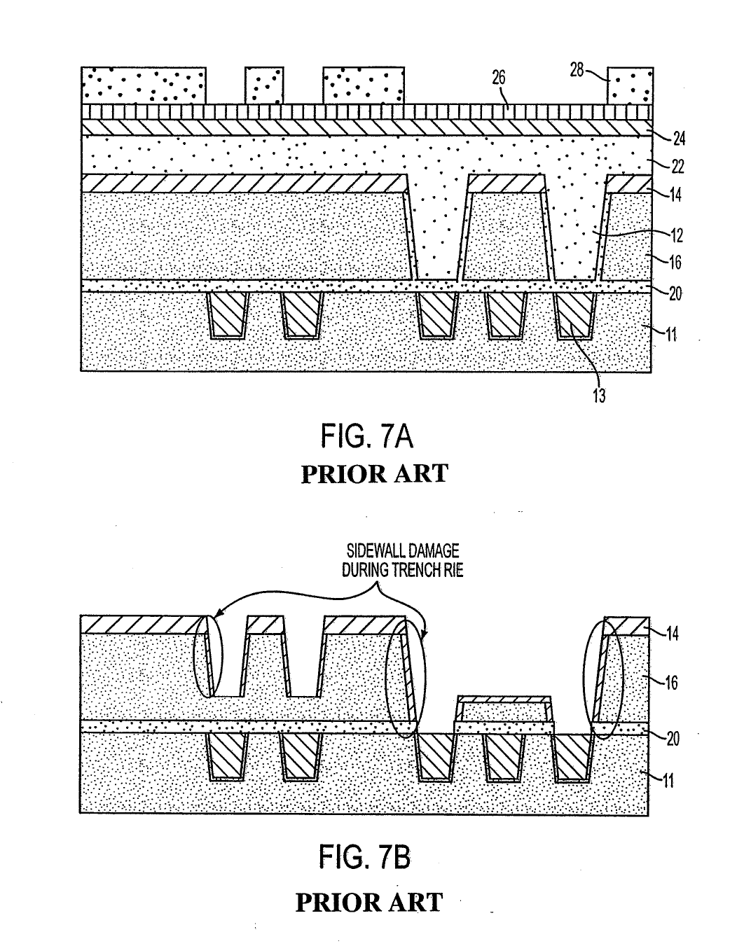

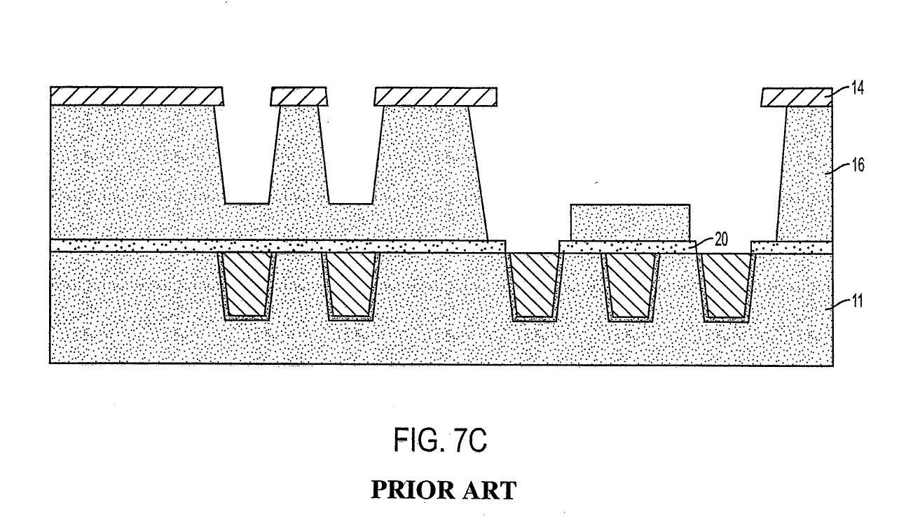

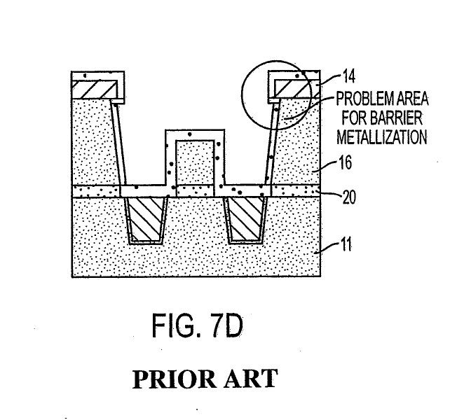

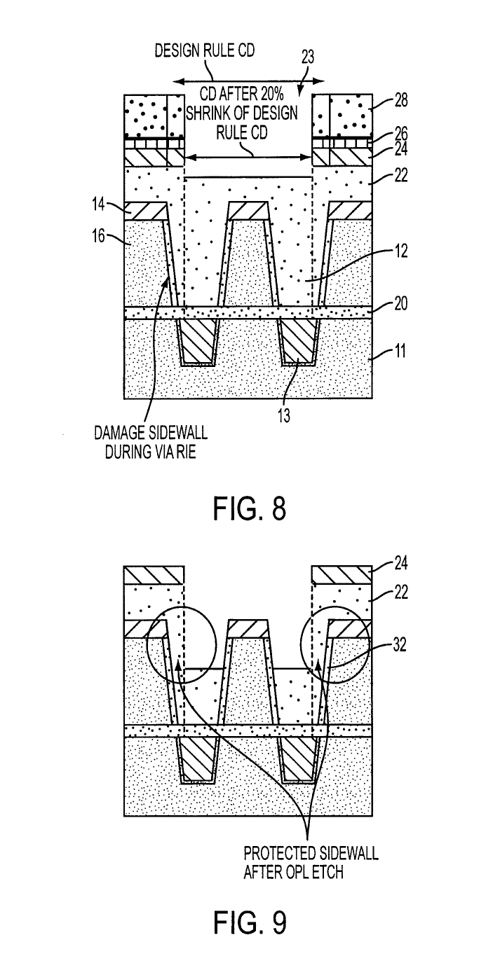

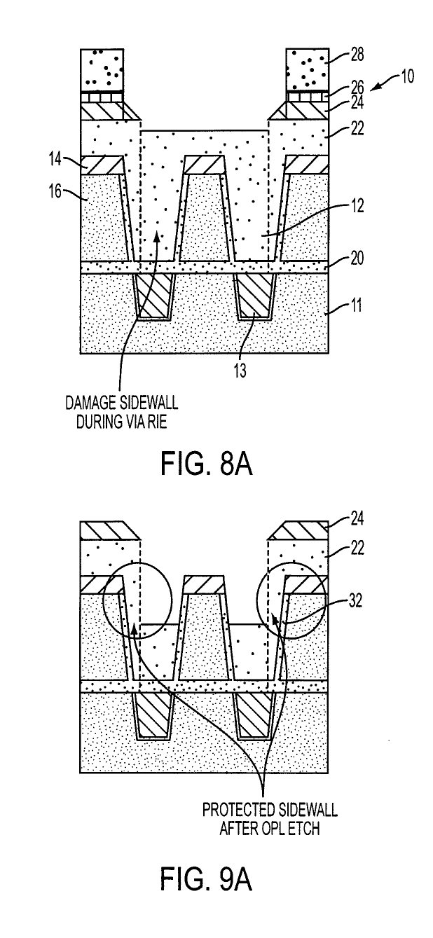

FIG. 8 shows a cross section of a portion of an IC 10 in which vias 12 have already been formed. The portion of the IC 10 includes a substrate 11, on which metal lines 13 have been formed. An etch stop layer 20 covers the metal lines 13 and the substrate 11. A ILD layer 16 covers the etch stop layer 20 and into which vias 12 have been formed, as described above with respect to FIGS. 1 and 2. The vias 12 are filled with an OPL layer 22. The top of the ILD layer 16 is covered with a hard mask 14. On top of the OPL layer 22 which extends out of the vias 12 and onto the oxide hard mask 14, are formed an oxide like over layer 24, an anti-reflective layer 26, and a photo-resist 28. As shown in FIG. 8, the photo-resist 28 has already been patterned and anti-reflective layer 26 and the OLO 24 have already been etched. The removal of the anti-reflective layer 26 material may be accomplished using chemistries including, for example, CF₄, CF₄/O₂, and CF₄/O₂/Ar. The opening 23 formed in the photo-resist 28 sets the size for the subsequent openings that are etched into the anti-reflective layer 26 and the OLO layer 24. As shown in FIG. 8 this opening is formed >20% smaller than the ultimate design rule for the IC design calls for. Thus if an opening of 100 nm were called for by the design of the IC 10, then the opening 23 would be formed at approximately 80 nm, first in the photo-resist 28 and subsequently by etching in the anti-reflective layer 26 and the OLO layer 24.

The effect of this shrinking the CD of the opening 23, is shown in FIG. 9, wherein anisotropic etching of the OPL layer 22 is undertaken. The anisotropic etching is used as it ensures vertical sidewalls to be formed in the OPL layer 22. Etching chemistries for the OPL etch includes N₂/CO₂, N₂/CO₂/O₂, and Ar/O₂. The sidewalls are formed substantially in a straight line with the sides of the opening 23 and cause the OPL 22 not to be etched all the way to the via side walls 32.

There are a variety of methods for changing the CD of the opening, such that the OPL layer 22 is not etched to expose the sidewalls 32 of the via 12. One method utilizing the IC manufacturing equipment is direct current DC superposition during the reactive-ion etch (RIE) process. In this process the voltage V_{DC} applied to one of the electrodes during the RIE process is varied to change the CD. The increase in V_{DC} causes an increase in the plasma density within the reaction vessel. The change in plasma density helps to stimulate the polymerization chemistry while at the same time the plasma potential decreases which reduces the ion energy available for the reactive ion etch.

In one non-limiting example the CD was decreased from 145 to 118 to 100 nm by changing the V_{DC} from 0 to 500 to 750 V_{DC}. Thus in an instance where the design dimensions is 140 nm application of a 750V_{DC} superposition during the RIE process would easily result in a reduction of the CD by approximately 32%

Another method of changing the CD is to change an amount of CHF₃ used during the RIE process. In one embodiment, this is achieved by adjusting the proportion of polymerizing gases used in the plasma. It has been observed that as the ratio of CHF₃ to CF₄ is increased, more sidewall polymer is generated which decreases the size of the opening.

In one experiment, where all other parameters where kept constant, varying amounts of CF₄/CHF₃ were used. Initially, mixture of 150/0 CF₄/CHF₃ SCCM was used. Subsequently a mixture of 150/20 CF₄/CHF₃ SCCM was used. Finally a mixture of 150/40 CF₄/CHF₃ SCCM was used. Measurements were made at a total of nine locations in each test. The results were as follows.

| | Etch CD (nm) | | |
|---|---|---|---|
| Site | 0 CHF₃ | 20 CHF₃ | 40 CHF₃ |
| 1 | 91.9 | 85.0 | 76.2 |
| 2 | 93.6 | 86.2 | 77.5 |
| 3 | 91.0 | 85.2 | 80.5 |
| 4 | 83.2 | 79.9 | 74.4 |
| 5 | 88.0 | 86.1 | 78.8 |
| 6 | 88.4 | 83.1 | 75.3 |
| 7 | 89.6 | 82.8 | 76.1 |
| 8 | 91.5 | 84.1 | 78.3 |
| 9 | 90.5 | 82.6 | 77.8 |
| Average | 89.7 | 83.9 | 77.2 |

Accordingly, by adding more CHF₃ the size of the CD can be reduced. Those of skill in the art will appreciate that other combinations of polymerizing gasses may also be used including but not limited to C4F8/Ar, CF4/CH2F2/Ar, CF4/CHF3/Ar, and others, also the exact combination of gasses may vary depending upon the material of the OPL layer 22.

Alternatively, as shown in FIG. 8a, the OLO 24 may be etched such that it is tapered, though typically a taper may be formed as a result of the polymerization process, this is generally looked at as undesirable except as used to produce a taper in the via 12. In contrast, the instant process utilizes this taper formed on the OLO 24 to advantageously impact the process as will be described below. This tapering is in the direction of the center of the opening defined by the photo-resist 28. Chemistries for opening the OLO include for example, C₄F₈/Ar, CF₄/CH₂F₂/Ar, CF₄/CHF₃/Ar. Other possibilities exist for creating the taper including new reactive ion etching devices which are able shrink the critical dimension CD in a specified area and may be useful in undertaking the process described herein.

The effect of this tapering of the oxide-like over layer 24, is shown in FIG. 9a, which much like FIG. 9 shows the process following anisotropic etching of the OPL layer 22. The anisotropic etching is used as it ensures vertical sidewalls to be formed in the OPL layer 22. The sidewalls are formed directly beneath the tapered portions of the OLO and cause the OPL not to be etched all the way to the via side walls 32.

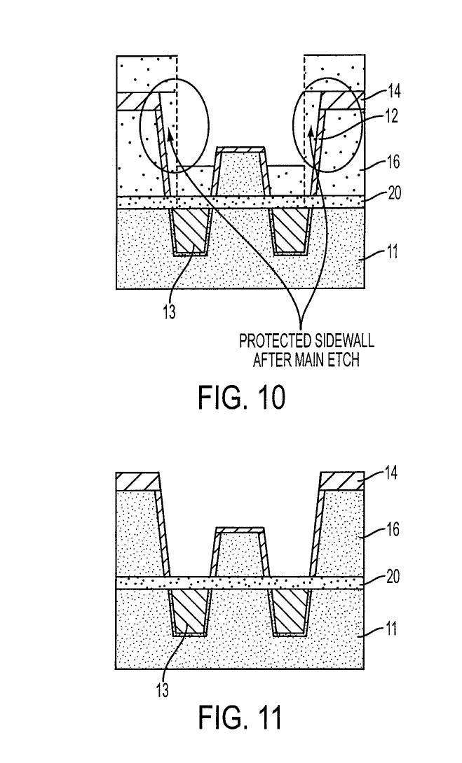

Next, as shown in FIG. 10, the main trench etch is undertaken, again using an anisotropic process, with the result being that the sidewalls of the via 12 are not actually affected by the etch. This etch may be accomplished using chemistries include C₄F₈/Ar/N₂, CF₄/Ar, CF₄/CH₂F₂/Ar/O₂, CF₄/CHF₃/Ar/O₂ etch. FIG. 10a is a photograph showing the via 12 sidewalls 32 protected by the OPL layer following the via etch.

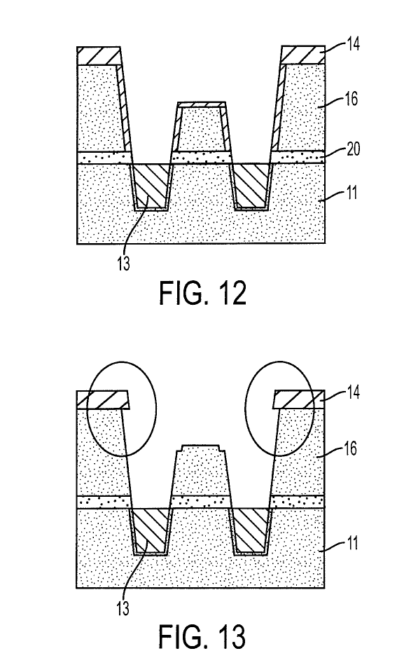

In FIG. 11, by using a low pressure stripping method, followed by an over ash with a high pressure process, or wet cleans and solvents, any remaining organic material of the OPL is cleared away. Finally, as shown in FIG. 12 an anisotropic etch stop removal process can be used to remove the etchstop at the bottom of the via 12. This may be accomplished using chemistries including CF₄/CH₂F₂/Ar/CO₂, or N₂ or O₂. This results in a trench and vias with minimal undercut after DHF clean as shown in FIG. 13.

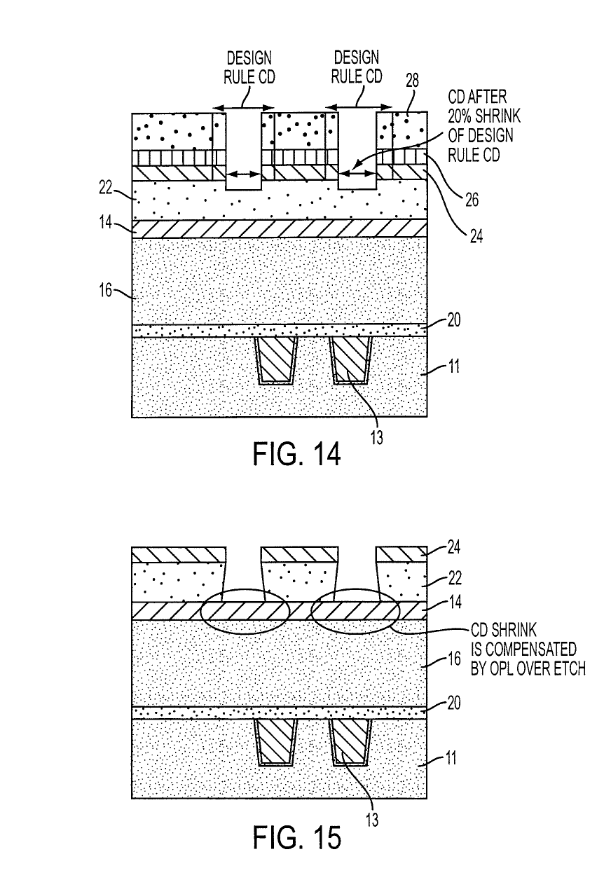

By using such a scheme for forming the vias 12 and trenches 34 without damaging the sidewalls of the vias, one may believe that in a trench only portion of the IC 10, the dimension of such a trench might be reduced. This might be expected because the CD of the trench would appear to have been reduced by, for example, 20% using the preceding processes. However, experience shows that following the OLO etch shown in FIG. 14 of a trench only structure, the OPL etch in the trench only area sees more over etch which actually opens the bottom of trench (with no footing) and compensates for the CD which was reduced after the OLO open step. This is due to the selectivity of the OPL etching materials to oxide hard mask and despite their anisotropic nature, upon reaching the hard mask 14, the OPL layer is opened laterally to compensate a little bit of the CD shrink caused by the tapering of the OPL layer.

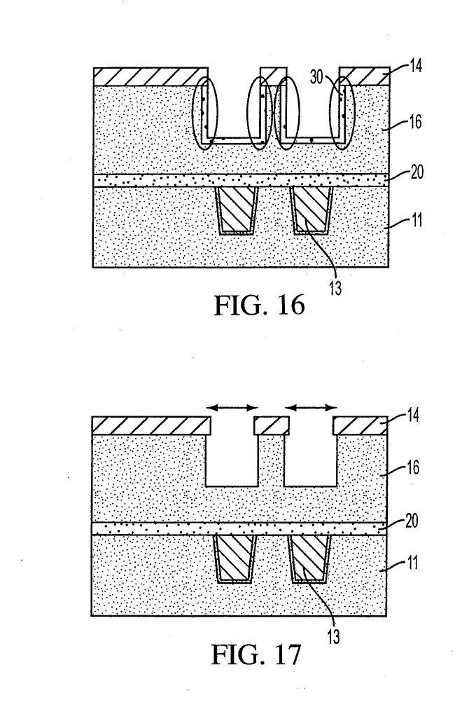

FIG. 16 shows the trench only structure following subsequent hard mask removal, etch of the low-k dielectric, etch stop removal and ashing steps. As a result of these steps, the low-k dielectric 16 of the trench only structure is damaged through depletion of carbon in the sidewall material. Turning it into an oxide-like material 30. The same process would occur twice in the via areas where its not protected by the OPL during at least some of these steps. The oxide like material 30 can then be removed as shown in FIG. 17 through dilute HF cleaning. Following the HF clean the size of the trench increases approximately 10-30% of the CD and thus then narrowing of the CD by the processes discussed above is fully compensated for.

This increase in trench size in the trench only portion of the IC 10 through the dilute HF clean is another portion of the equation in regulating the changes in CD following the initial reduction described above to protect the sidewalls of the trench. Using the two similar processes described above where the etching is done with a combination of CF₄/CHF₃ in a ratio of 150/x sccm, the damage to the sidewalls, which is subsequently removed as shown in FIGS. 16 and 17, can be determined. In process 1, 0 CHF₃ was used and in process 2, 40 CHF₃ was used.

| | Process 1 with 0 CHF₃ | | | | | |
|---|---|---|---|---|---|---|
| | | CD | | Process 2 with 40 CHF₃ | | |
| | Etch | after DHF | | 40 | CD after DHF | |
| | CD | Clean | Damage | CHF₃ | Clean | Damage |
| 1 | 91.9 | 106.7 | 14.8 | 76.2 | 112.1 | 35.9 |
| 2 | 93.6 | 109.0 | 15.4 | 77.5 | 108.3 | 30.8 |
| 3 | 91.0 | 109.4 | 18.4 | 80.5 | 103.6 | 23.1 |
| 4 | 83.2 | 102.1 | 18.9 | 74.4 | 102.7 | 28.3 |
| 5 | 88.0 | 104.8 | 16.8 | 78.8 | 98.8 | 20.0 |
| 6 | 88.4 | 102.3 | 13.9 | 75.3 | 100.2 | 24.9 |
| 7 | 89.6 | 103.2 | 13.6 | 76.1 | 97.9 | 21.8 |
| 8 | 91.5 | 105.3 | 13.8 | 78.3 | 95.3 | 17.0 |
| 9 | 90.5 | 103.0 | 12.5 | 77.8 | 93.7 | 15.9 |
| Average | 89.7 | 105.1 | 15.3 | 77.2 | 101.4 | 24.2 |

By the foregoing example, the use of the CHF₃ in the etching can be used first to reduce the size of the CD to prevent removal of all of the OPL layer from the via sidewall and thus reduce the damage to the sidewalls initially. Finally the damage layer in trench only structures are removed through cleaning using dilute HF which compensates for the initial reduction in the CD in the trench only portion of the IC.

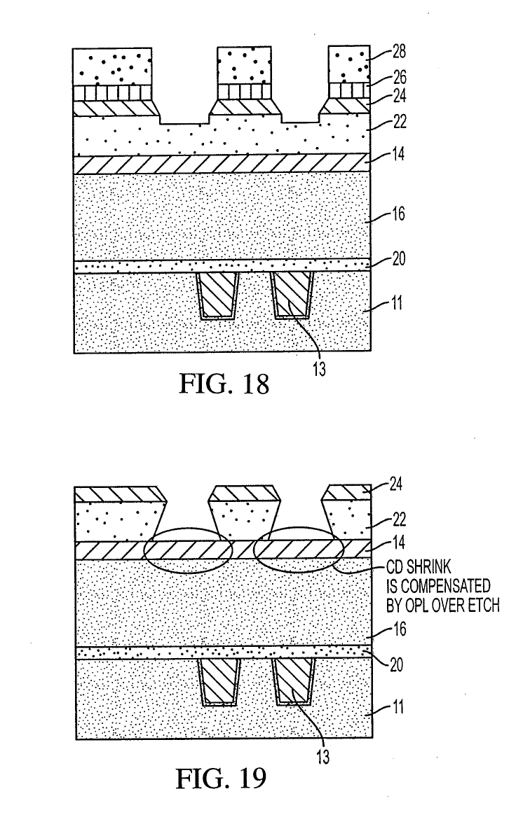

FIGS. 18 and 19 show the result of the OPL over etch described above in the scenario where a tapered OLO layer 24 is used. As before, the over etch compensates a little bit for the decrease in the CD caused by the taper by removing any footing at the bottom of OPL and creates opening for the trenches at OLO step.

The above description, including the specification and drawings, is illustrative and not restrictive. Many variations of the invention will become apparent to those of skill in the art upon review of this disclosure. Various features and aspects of the above-described disclosure may be used individually or jointly. Further, the present disclosure can be utilized in any number of environments and applications beyond those described herein without departing from the broader spirit and scope of the specification. The scope of the invention should, therefore, be determined not with reference to the above description, but instead should be determined with reference to the appended claims along with their full scope of equivalents. In addition, it will be recognized that the terms “comprising,” “including,” and “having,” as used herein, are specifically intended to be read as open-ended terms of art. The term “or” as used herein is not a logic operator in an exclusive sense unless explicitly described as such.

1. A method of minimizing undercut of a hard mask in an integrated circuit (IC) structure comprising the steps of:
providing an IC structure including a substrate, a interlayer dielectric layer, and a hard mask;
forming a via in said IC structure;
depositing an organic planarizing layer (OPL) over the IC structure such that it fills the vias formed therein;
forming a masking structure layer over the OPL; and
forming an opening in the masking structure that has a critical dimension (CD) smaller than an opening design dimension;
anisotropic etching the OPL such that sidewall of the via remains covered with the OPL while forming a trench;
removing any remaining OPL on the sidewalls and trench, wherein the undercut of the sidewalls with respect to the hard mask is minimized by the covering of OPL during the anisotropic etching process.

2. The method of claim 1, wherein removing of the remaining OPL is by a low pressure strip process.

3. The method of claim 2, wherein the low pressure strip process is followed by an over-ashing step.

4. The method of claim 1, wherein the removing step is achieved by wet etching and the use of solvent.

5. The method of claim 1, wherein the photo-resist includes patterning for a trench only portion of the IC.

6. The method of claim 1, wherein following reduction of the CD in the masking structure layer, overetching of the OPL layer achieves an opening in the OPL without any footing at the bottom of OPL.

7. The method of claim 1, further comprising a step of anisotropically removing anetchstop layer in the via to expose the one or more metal lines.

8. The method of claim 7, further comprising a step of barrier metalization.

9. The method of claim 8, further comprising a step of Cu seeding.

10. The method of claim 1, wherein the a interlayer dielectric layer is a low-k dielectric.

11. The method of claim 1, wherein the interlayer dielectric layer is an ultra low-k dielectric.

11. The method of claim 1 further comprising a step of forming an anti-reflective coating, and a patterned photo resist over the OPL.

12. The method of claim 1, wherein the etching of the masking structure is preceded by removal of a portion of the anti-reflective coating to expose the masking structure.

13. The method of claim 1, wherein the opening in the masking structure layer that has a CD smaller than the design dimension is formed by etching the masking structure to form a tapered opening in the masking structure layer.

14. The method of claim 1, wherein the wherein the opening in the masking structure that has a CD smaller than the design dimension is formed by direct current (DC) superposition during reactive ion etch (RIE) formed on the IC.

15. The method of claim 14, wherein the DC superposition uses 500 volts.

16. The method of claim 14, wherein the DC superposition uses 750 volts.

17. The method of claim 1, wherein the opening in the masking structure layer that has a CD smaller than the design dimension is formed by including CHF₃ in the etch chemistry.

18. The method of claim 17, wherein the mixture of CH₄ to CHF₃ is 150/20 sccm.

19. The method of claim 18, wherein the mixture of CH₄ to CHF₃ is 150/40 sccm.

20. The method of claim 1 wherein the CD of the opening in the masking structure layer is reduced 20% compared to the design dimension.

21. The method of claim 1, wherein the masking structure is an oxide-like over-layer (OLO).
